(19) United States
(12) Patent Application Publication
(10) Pub. No.: US 2006/0148139 A1
(43) Pub. Date: Jul. 6, 2006

(54) Selective second gate oxide growth

(76) Inventors: Hock Kar Ng, Singapore (SG); Soo Lai Lim, Singapore (SG)

Correspondence Address: HARNESS, DICKEY, & PIERCE, P.L.C, 7700 BONHOMME, STE 400, ST. LOUIS, MO, 63105, US

(21) Appl. No.: 11/030,497

(22) Filed: Jan. 6, 2005

(51) Int. Cl. H01L 21/00; H01L 21/84; H01L 21/336

(52) U.S. Cl. 438/151

(57) ABSTRACT

The invention comprises a method of dual oxide gate formation comprising the steps of forming a first gate oxide and forming a second gate oxide using in-situ steam generation oxidation.

### BACKGROUND OF THE INVENTION

1. Field of the Invention

The present invention relates to a method for forming dual gate oxide and in particular to a method of forming dual gate oxide where the second gate is formed using in-situ steam generation.

2. Description of the Prior Art

Semiconductor devices are continually shrinking in size. Smaller semiconductor devices include less material which cuts down on manufacturing costs and have higher performance than larger semiconductor devices. Higher performance occurs in the faster speed of the smaller devices and the lower power consumption. This has lead to the integration of various systems onto a single chip. The advantages of combining systems onto a single chip include shorter interconnections between the devices and a decrease in the power needed to drive the interconnections.

To realize the advantages of combining systems onto a single chip gates on the chip need to be formed with different oxide thicknesses. For example, high voltages and comparatively thick gates are needed for input/output I/O connections whereas low voltages and comparatively thin gates are needed for fast logic.

One solution proposed for this problem includes growing a layer of thermal oxide, a photo step, followed by the removal of the open oxide structures, and a final re-growth of the oxides to the desired thickness. In this process the oxide etching step in critical and requires excellent uniformity within the wafer and wafer to wafer. This process relies on a highly uniform oxide etching process.

Another solution proposed for this problem involves doping the wafer on which the gates are grown. Using Ar⁺ and N⁺ implantation different oxide growth rates can be achieved in the differently doped regions.

Yet anther method for producing dual oxide gate growth is to grow a first gate and then grow the second gate. The disadvantage of this method is that the second gate growth affects the first gate and adds oxide to the first gate. This leads to an unpredictable thickness in the first gate which affects the chip performance.

### BRIEF SUMMARY OF THE INVENTION

It is an object of the present invention to provide an improved or alternative method for dual oxide gate formation, or to at least provide a useful choice.

In broad terms in one aspect the invention comprises a method of dual oxide gate formation comprising the steps of forming a first gate oxide and forming a second gate oxide using in-situ steam generation oxidation.

Preferably a first gate oxidation is formed using a furnace. In alternative embodiments ISSG can be used for form a first gate oxidation. In further alternative embodiments any suitable method may be used.

Preferably a second gate oxide is grown at a temperate between about 870° and 930° C.

Preferably the hydrogen gas ratio during the second gate oxide formation is less than one percent.

Preferably the second gate oxide is grown at a pressure between 1.333 kPa and 1.733 kPa. Ideally the pressure for the second gate oxide is about 1.533 kPa.

Preferably the second gate oxide is grown for between 20 and 40 seconds.

### BRIEF DESCRIPTION OF THE SEVERAL VIEWS OF THE DRAWINGS

The invention will be further described by way of example only and without intending to be limiting with reference to the following drawings, wherein:

FIG. 1 shows the standard flow for dual oxide gate growth;

FIG. 2 shows the flow for dual oxide gate growth of the invention;

FIG. 3 shows the change in second gate oxide thickness as the furnace temperature changes;

FIG. 4 shows the change in uniformity of the oxide growth with change in pressure; and

FIG. 5 shows the change in second gate thickness with change in process time.

### DETAILED DESCRIPTION OF THE INVENTION

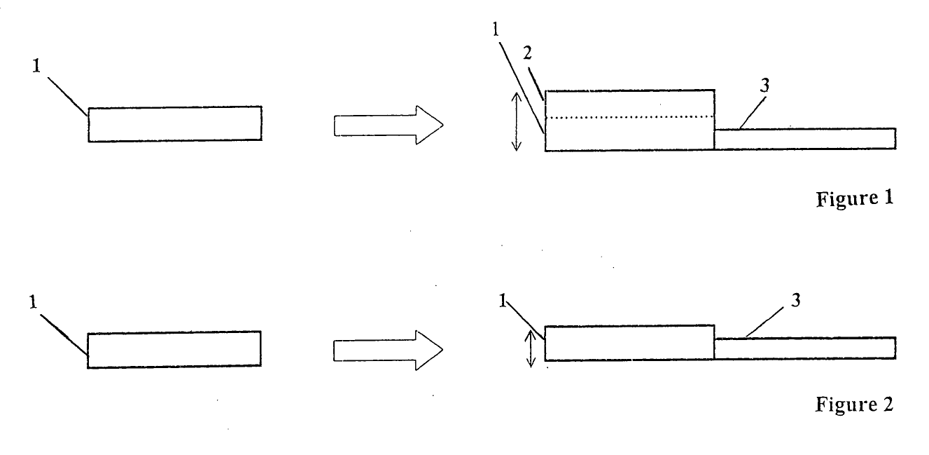

FIG. 1 shows the process flow in a standard dual gate oxide growth system. To produce the dual gate oxide a first gate oxide 1 is grown on a wafer. In one embodiment the first gate oxide is grown by furnace wet oxidation or pyro oxidation. This process involves exposing the wafer to steam at 800 to 900 degrees. The steam for the wet oxidation is generated by combustion of H₂ and O₂. The steam is transported into the furnace through heated liens at ambient atmospheric pressure. THE steam (H₂O) diffuses through the growing oxide to react at the propagating SiO₂—Si reaction front wafer. In alternative embodiments any suitable process may be used to form the first gate oxide. For example, ISSG may be used to form the first gate oxide. After the first layer of oxide 1 is grown a second layer of oxide 3 is grown using a similar process.

As can be seen in FIG. 1 when the second oxide gate is formed this increases the thickness of the first oxide gate. For example if the first oxide gate is grown to 60 Å and the second oxide layer is 32 Å will add additional oxide to the first oxide gate, making it for example 73 Å thick.

FIG. 2 shows the process flow of the dual gate oxide growth system of the invention. In this process after the first oxide gate 1 is formed a second oxide gate is formed by in-situ steam generation (ISSG). As can be seen in FIG. 2 this process forms only the second oxide gate and does not increase the thickness of oxide gate 1. In the example shown in FIG. 2 the first gate has an original thickness of 60 Å and the second gate has a thickness of 32 Å. After formation of the second gate the thickness of the first gate is still 60 Å.

In the ISSG process lean premixed H₂ and O₂ are introduced into a rapid thermal processing reactor in which a wafer is heated. Combustion is induced in close proximity to the silicon surface to generate free radical chemistry such at O and OH atoms. The free radical atoms are responsible for oxidation of the wafer surface. ISSG oxide quality is superior to furnace oxide due to its radical oxidation.

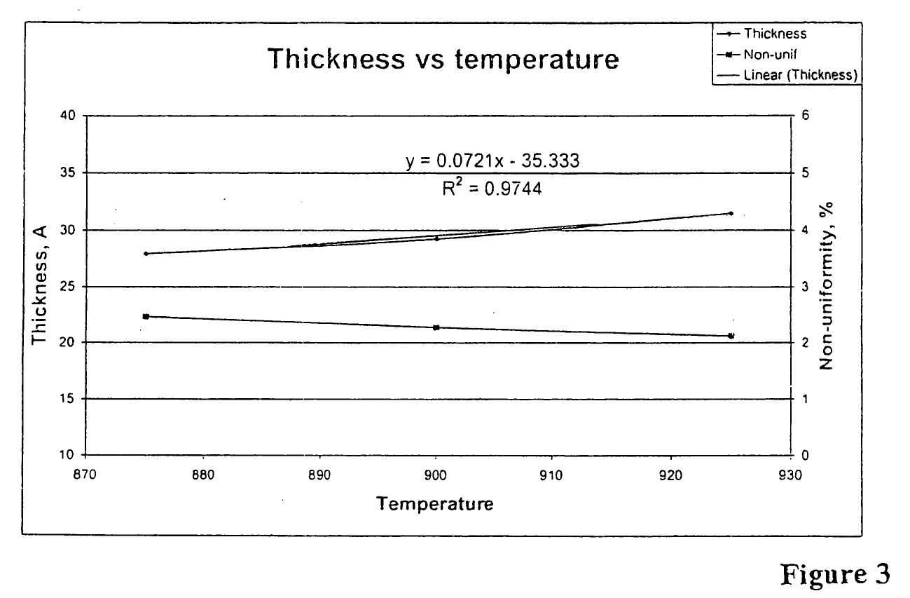

Table 1 and FIG. 3 show the effect of temperature on second oxide growth using ISSG. In this case the exposure time of the wafer to ISSG processing was constant at 40 seconds for all the runs. As can be seen from Table 1 and FIG. 3 the change in temperature between about 875 and 925 degrees C. changes the thickness of the oxide on the wafer. Each degree increase in temperature in this range results in about 0.07 Å increase in gate thickness. The non-uniformity of the oxide growth also decreases with increasing temperature.

TABLE 1

| | Thickness of | |
|---|---|---|
| Temperature | gate oxide | Non-uniformity |
| 875 | 27.9246 | 2.4734 |
| 900 | 29.2213 | 2.2805 |
| 925 | 31.5297 | 2.1236 |

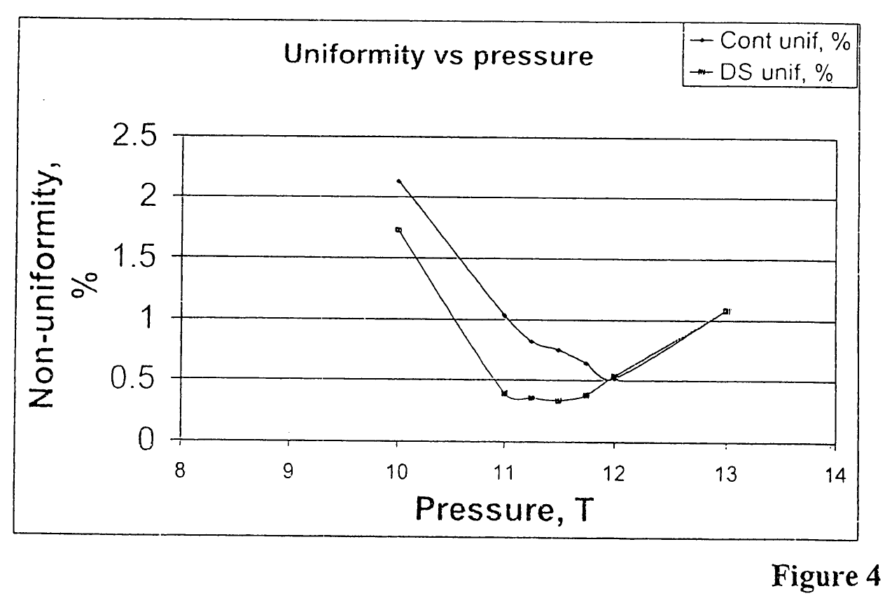

Table 2 and FIG. 4 show the effect of furnace pressure on the growth of the second oxide gate. It should be noted that the pressure dependence of the ISSG process with vary with each furnace and the results shown in Table 2 and FIG. 4 may vary. The optimal pressure base it the one that provides the best uniformity. As can be seen in Table 2 and FIG. 4 this is provided by a pressure of about 1.533 kPa for the furnace used. The pressure used will depend on the uniformity within the wafer,

TABLE 2

| Pressure (kPa) | Cont uniformity % | DS uniformity % |
|---|---|---|
| 1.333 | 2.1309 | 1.7265 |
| 1.466 | 1.0365 | 0.3926 |
| 1.5 | .08234 | 0.3573 |
| 1.533 | 0.7514 | 0.3344 |
| 1.566 | 0.6408 | 0.3795 |
| 1.6 | 0.5181 | 0.5335 |
| 1.733 | 10.854 | 1.0836 |

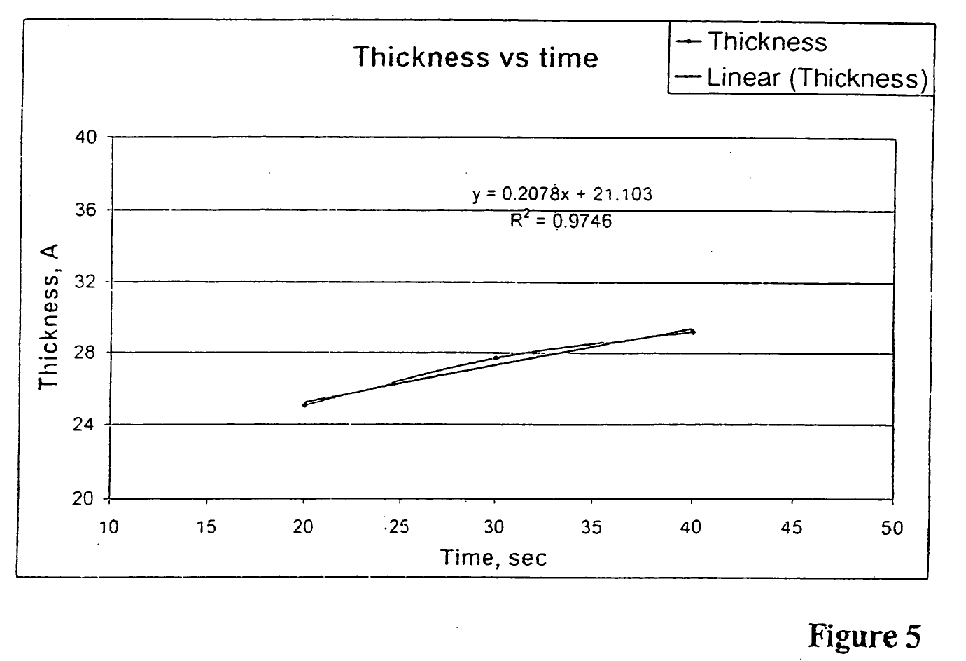

Table 3 and FIG. 5 show the relationship between second oxide growth using the ISSG process and the time it takes to grow the oxide in the furnace. This process time is about 0.2 Å/second on bare silicon. In the process shown in Table 3 and FIG. 5 the gas ratio is H₂%<1%. The result of no oxide growth on the first gate is based on ISSG gas ratio of low H₂%. In the example shown in FIG. 5 and Table 3 the gas rate is 9.9 standard liters per minute of O₂ and 0.1 standard liters per minute of H₂. The very low hydrogen gas percentage will cause radical oxidation (OH—, O—, H+) where the residence time of the radical is short, and thus there is not enough time for the radicals to penetrate into the thick oxide for further oxidation. As expected the thickness of the second gate oxide increases with the increased furnace time.

| Time (seconds) | Thickness Å |
|---|---|
| 20 | 25.0655 |
| 30 | 27.7241 |
| 40 | 29.2213 |

The combination of the low furnace temperature <900° C. and the gas ratio of <1% hydrogen result in little or no oxide growth on the first gate.

Table 4 shows results of the process of the invention and the standard dual gate process. The first column contains the gate thickness of the first oxide gate after forming the first oxide gate. The second column contains the first gate thickness after forming, the second oxide gate and the third column contains the change in thickness of the first gate from the formation of the first gate to the formation of the second gate. The first two rows of table 1 are for processes where the first and second gates were formed using the standard dual gate process. The second two rows of Table 4 are for processes where the second gate was formed using the process of the invention.

As can be seen from the first two lines of this table when second gate is formed there is oxide growth on the first gate. In these cases the oxide growth was just over 13 Å or about 22% of the thickness of the first gate before the second gate is formed. The rows illustrating the process of the invention show that there is little oxide growth on the first gate that occurs when the second gate is being formed. In these cases the oxide growth is about 0.25 Å or about 0.4% of the thickness of the first gate before the second gate is formed. These experiments illustrate the effectiveness of the invention in producing minimal oxide growth on the first gate during formation of the second gate.

TABLE 4

| | | First gate | |
|---|---|---|---|
| | | thickness | Difference in |
| | First gate thickness | after formation of | thickness |
| | before formation of | the second | in first |
| | the second gate (Å) | gate (Å) | gate (Å) |
| Run 1 (standard | 59.84 | 73.18 | 13.34 |
| process) | | | |
| Run 2 (standard | 59.75 | 73.2 | 13.45 |
| process) | | | |
| Run 1 (ISSG | 59.95 | 60.1599 | 0.2099 |
| process) | | | |
| Run 2 (ISSG | 59.81 | 60.0615 | 0.2515 |
| process) | | | |

Table 5 shows a further comparison between the standard process and the process of the invention. The first row of Table 5 relates to the first gate and the second row related to the second gate. The first column in Table 5 relates to the process of the

invention and the second column relates to the standard process. The third column shows the difference between the thickness of the gates produced by the standard process and the process of the invention and the final column provides this difference as a standard deviation.

As can be seen from Table 5 there is little difference in the thickness of the second gate regardless of the method used to form the second gate. However, there is a marked difference in the thickness of the first gate depending on the method used to form the second gate. When the second gate is formed using the standard process the eventual thickness of the first gate is much greater than when the second gate is formed using the method of the invention.

TABLE 5

| | | Standard | Difference in | |
|---|---|---|---|---|
| | ISSG method - | process - gate | thickness of | |
| | gate thickness Å | thickness Å | gates (Å) | Sigma |
| First gate | 65.3 | 71.7 | 6.36 | −22.93 |
| Second gate | 39.8 | 40.2 | 0.44 | −2.59 |

The foregoing describes the invention including preferred forms thereof. Alterations and modifications as will be obvious to those skilled in the art are intended to be incorporated in the scope hereof as defined by the accompanying claims.

1. A method of selective second gate oxide growth comprising the steps of
forming a first gate oxide, and
forming a second gate oxide using in-situ steam generation oxidation.

2. A method of selective second gate oxide growth as claimed in claim 1 wherein a first gate oxidation is formed using a furnace.

3. A method of selective second gate oxide growth as claimed in claim 1 wherein a first gate oxidation is formed using ISSG.

4. A method of selective second gate oxide growth as claimed in claim 1 wherein the second gate oxide is grown at a temperature between about 870′ and 930° C.

5. A method of selective second gate oxide growth as claimed in claim 1 wherein the hydrogen gas ratio during the second gate oxide formation is less than one percent.

6. A method of selective second gate oxide growth as claimed in claim 4 wherein the hydrogen gas ratio during the second gate oxide formation is less than one percent.

7. A method of selective second gate oxide growth as claimed in claim 1 wherein the second gate oxide is grown at a pressure between 1.333 kPa and 1.733 kPa.

8. A method of selective second gate oxide growth as claimed in claim 7 wherein the pressure for the second gate oxide is about 1.533 kPa.

9. A method of selective second gate oxide growth as claimed in claim 1 wherein the second gate oxide is grown for between 20 and 40 seconds.
